(19) United States
(12) Patent Application Publication
(10) Pub. No.: US 2012/0127670 A1
(43) Pub. Date: May 24, 2012

(54) MODULE HOUSING AND METHOD FOR MANUFACTURING A MODULE HOUSING

(76) Inventor: Ronny Ludwig, Bodelshausen (DE)

(21) Appl. No.: 12/739,608

(22) PCT Filed: Sep. 29, 2008
(86) PCT No.: PCT/EP2008/062992

§ 371 Date: Apr. 23, 2010

(30) Foreign Application Priority Data
Oct. 30, 2007 (DE) 102007051870.8

(51) Int. Cl. H05K 7/00; B21B 1/46

(52) U.S. Cl. 361/728; 29/527.2

(57) ABSTRACT

A module housing having an inner housing, an outer housing and a connection element is provided, the inner housing having at least one component and being completely enclosed by the outer housing in a form-locking manner, and the connection element being enclosed in a first subsection by the inner housing in a form-locking manner, wherein the connection element has electrical plug contacts in a third subsection.

### FIELD OF THE INVENTION

The present invention relates to a module housing.

### BACKGROUND INFORMATION

Module housings are described in German Patent Application No. DE 10 2004 058 815 A1. Here, a chip module is described having a housing body and a “lead frame”, the housing body having a component, in particular a semiconductor component, and the lead frame being enclosed in a subsection by the housing body in a form-locking manner. In a manufacturing process, the component is first mounted on the “lead frame” and is subsequently spray-coated with epoxide to produce the housing body. Subsequently, the lead frame is stamped so as to produce individual chip modules. There is no provision for the housing body of the chip module and a second subsection of the lead frame to be enclosed by an outer housing by spray-coating such that additional method steps are necessary for contacting the component or the chip module, typically by mounting and soldering processes on a circuit board, and additional method steps are necessary for forming a protective housing or for inserting the housing body into a protective housing.

### SUMMARY

An example module housing of the present invention and example method for manufacturing a module housing of the present invention may have the advantage that an integration of at least one component into an outer housing is made possible by process steps that are comparatively readily controllable, customer-specific and/or application-specific requirements with respect to the shape of the outer housing and/or the manner of electrical contacting being implementable in a simple manner and with a minimum of process cost. This is achieved, on the one hand, by the form-locking and/or integral connection between the outer housing and the inner housing such that, in contrast to the related art, no additional carrier element is required, which would necessitate a manufacture and an installation in additional cost-intensive method steps. Manufacturing the outer housing in a comparatively readily controllable spray-casting or molding process allows for a variable and flexible shaping of the outer housing so as to make the specific requirements with respect to the outer housing implementable in a simple manner. On the other hand, the connection element has the electrical plug contacts in the third subsection such that no additional elements are required for contacting the connection element or the at least one component, in particular via a pluggable contact. Particularly advantageously, the connection element thus functions to fasten the component mechanically and at the same time to contact it electrically such that, in contrast to the related art, no cards, circuit boards or additional plugs are required. Advantageously, a one-piece connection of the plug contact and a component contact is provided such that no additional conductor tracks and/or electrical contacts, which would have to be contacted in additional method steps, are required. The form-locking enclosure of the inner housing by the outer housing furthermore ensures a maximum protection and arresting function for the inner housing since the inner housing is mechanically fixed from all sides. In the related art, the inner housing is arrested only from one base side by an integral connection.

According to another preferred development, the outer housing has a plug, which at least partially envelops the electrical plug contacts, it being possible in particular to implement the electrical plug contact in a variety of shapes by appropriate stamping-bending processes. The outer housing and the plug are thus advantageously connected in one piece and manufacturable in a single and comparatively simple method step. The process of spray-coating and/or the implementation of the electrical plug contact in a variety of shapes allow in a simple manner for the implementation of various shapes of the outer housing and thus also of various plug shapes, in particular regulated and/or standardized plug types.

According to a preferred development, in the third subsection, the connection element has an electrical and/or mechanical connection to additional plug contacts such that the additional plug contacts may be particularly advantageously produced in material thicknesses that deviate from the material thickness or the material type of the connection element. This allows for a simple and cost-effective manufacture of a comparatively thin connection element in a stamping-bending process for example, while for implementing a specific plug standard having a respectively required material thickness of the plug contact, another material of the required thickness is used as the additional plug contact. Preferably, the additional plug contact is connected to the connection element in an electrically conductive manner, in particular by an integral, force-locking and/or form-locking connection.

According to a preferred development, the at least one component has an electrical and/or mechanical first contact to the connection element and/or in a second subsection the connection element is enclosed by the outer housing in a form-locking manner such that the connection element advantageously functions to fix the component mechanically and at the same time to contact the component electrically. Advantageously, no additional carrier elements and/or circuit boards or cards are required for contacting the component, which necessitate comparatively cost-intensive manufacturing methods and installation methods.

According to another preferred development, the connection element includes at least one electrically conductive conductor track, the conductor track respectively extending at least partially over the first, the second and the third subsection of the connection element. Advantageously, a simple electrical contact is thus made possible between the component and the connection element. Compared to the related art, the complexity of producing a contact is substantially reduced since only a single component is used for establishing a conductive connection from the plug contact to the component, and thus the cost-intensive manufacture, installation and contacting of circuit boards or cards is eliminated.

According to another preferred development, the inner housing and/or the outer housing comprise a molded housing or an spray-cast housing and/or the component comprises at least one semiconductor chip and/or at least one passive electrical component. The use of molded housings or spray-cast housings allows for the inner and outer housings to be shaped in a simple and variable manner, in particular since the molding process (e.g. “injection molding”) and/or the spray-casting process are comparatively readily controllable. Advantageously, the component or the inner housing comprises a multi-part arrangement of semiconductor chips and/or passive components, in particular a sensor chip and/or an ASIC, which are mounted on the first subsection of the connection element such that preferably also complex and multi-part electrical circuits are made possible within the inner housing. Particularly preferably, the first subsection of the connection element has multiple conductor tracks that are electrically insulated or disentangled from one another for receiving and wiring up multiple semiconductor chips and/or multiple passive components, the “footprint” of the respective semiconductor chips and/or of the passive components being especially preferably integrated into the connection element.

In accordance with another example embodiment of the present invention, a method for manufacturing a module housing is provided, the at least one component being mounted on the connection element in a first method step, the at least one component and the first subsection of the connection element being spray-coated for producing the inner housing in a second method step, and the inner housing and at least partially the connection element being spray-coated for producing the outer housing in a third method step. Advantageously, in only three comparatively simple and readily controllable method steps, it is thus possible to produce a module housing having a variably shaped outer housing. In particular, the use of additional carrier elements and circuit boards or cards is not required. The component is preferably soldered and/or glued onto the connection element, the connection element, particularly preferably, having the “footprint” of the component in the region of the component.

According to another preferred development, a fourth method step is performed between the first and the second method step for electrically contacting the at least one component, in particular by a bonding process. Advantageously, this allows for the component to be electrically wired up and, in particular, for multiple components to be electrically wired up to one another such that it is possible to produce preferably complex electrical circuits having multiple semiconductor chips and/or multiple passive components, the connection element particularly preferably having a plurality of conductor tracks in the first subsection, which are adapted to make optimum contact to multiple components or their “footprints”.

According to another preferred development, a fifth method step is performed between the second and the third method step for stamping and/or bending the connection element, preferably in the third subsection of the connection element, in order to produce the plug contacts. Advantageously, the plug contacts are thus produced in a simple manner without additional components, a variable adaptation of the shape of the plug contacts in the bending and/or stamping process being able to meet specific plug contact requirements, i.e., for regulated and/or standardized plug types. Clamping and/or spring bending points for example are preferably formed in the third subsection of the connection element such that an increased connection stability is achieved in the case of a plug connection between the plug and a corresponding counterpart of the plug. Particularly advantageously, the stamping process at the same time includes cutting excess connection element material from the connection element.

According to another preferred development, a plurality of components are mounted on a composite, in particular a composite lead frame, in the first method step, and the plurality of components is respectively spray-coated in the second method step to produce a plurality of inner housings, the composite being stamped in the fifth method step so as to form a plurality of connection elements that are partially enclosed by an inner housing. Advantageously, this allows for a comparatively cost-effective simultaneous production of a plurality of module housings. Particularly preferred is the simultaneous manufacture of a plurality of inner housings, which enclose the first subsections of the connection elements and respectively have at least the one component, the outer housing being produced in the third method step in individual shapes depending on the requirement such that it is possible to manufacture for example a plurality of identical module housings, in particular sensors, having different outer housings.

According to another preferred development, the second method step comprises a molding process, preferably an injection molding process being performed, and/or the third method step comprises a spray-casting process, a plastic spray-coating process being preferably performed. Advantageously, variable housing shapes are thus produced in a simple manner in a comparatively readily controllable and cost-effective manufacturing process.

Exemplary embodiments of the present invention are depicted in the figures and described in greater detail below.

### BRIEF DESCRIPTION OF THE DRAWINGS

FIG. 1 shows a schematic top view and a schematic lateral view of a module housing according to a first specific embodiment of the present invention.

FIG. 2a through FIG. 2g show schematic representations of further precursor structures of the module housing according to further specific embodiments of the present invention.

FIG. 3 shows a first precursor structure of a plurality of module housings according to one of the additional specific embodiments.

FIG. 4 shows an inner housing of a module housing according to one of the additional specific embodiments.

FIG. 5 shows components of the inner housing of a module housing according to one of the additional specific embodiments.

In the various figures, identical parts are provided with the same reference numerals and are therefore named only once.

### DETAILED DESCRIPTION OF EXAMPLE EMBODIMENTS

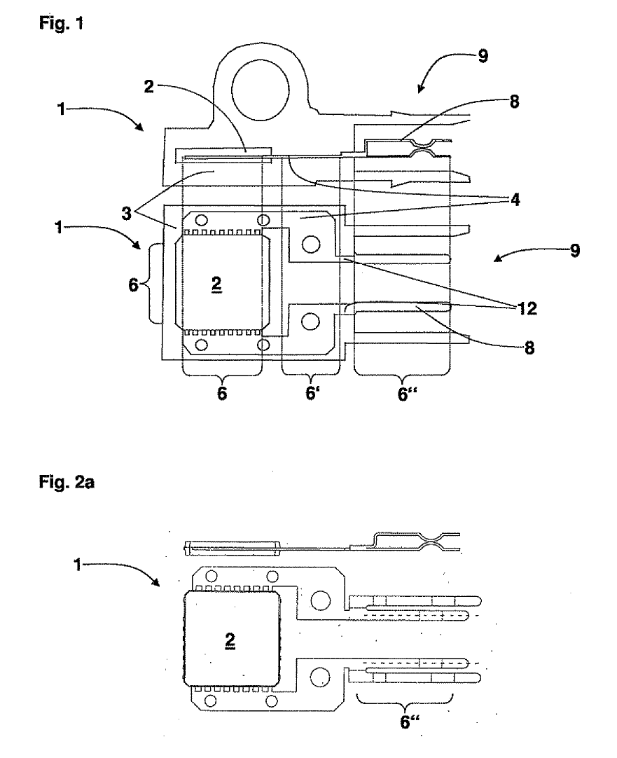

FIG. 1 shows a schematic top view or through-view and a schematic lateral view or lateral through-view of a module housing 1 according to a first specific embodiment of the present invention, module housing 1 having an inner housing 2, an outer housing 3 and a connection element 4, inner housing 2 having at least one component 5 and connection element 4 being enclosed in a first subsection 6 by inner housing 2 in a form-locking manner, and furthermore connection element 4 being enclosed in a second subsection 6′ and inner housing 2 being enclosed entirely by outer housing 3, respectively in a form-locking manner. Outer housing 3 further comprises a plug 9 for contacting connection element 4, components 5 (not shown) having electrical and mechanical first contacts 7 to connection element 4, and connection element 4 in a third subsection 6″ functioning as an electrical plug contact 8 of a plug 9. For the purpose of electrically contacting components 5, connection element 4 has at least two electrically conductive conductor tracks 12, which extend over the first, second and third subsection 6, 6′, 6″. Inner housing 2 comprises preferably molding housings, which are manufactured by injection molding processes using epoxide, while outer housing 3 preferably comprises plastic housings, which are manufactured by a spray-casting process. Plug contacts 8 particularly preferably have clamping and/or spring bending points in the third subsection 6″ such that an increased stability is achieved in the case of a plug connection between plug 9 and a corresponding counterpart of the plug.

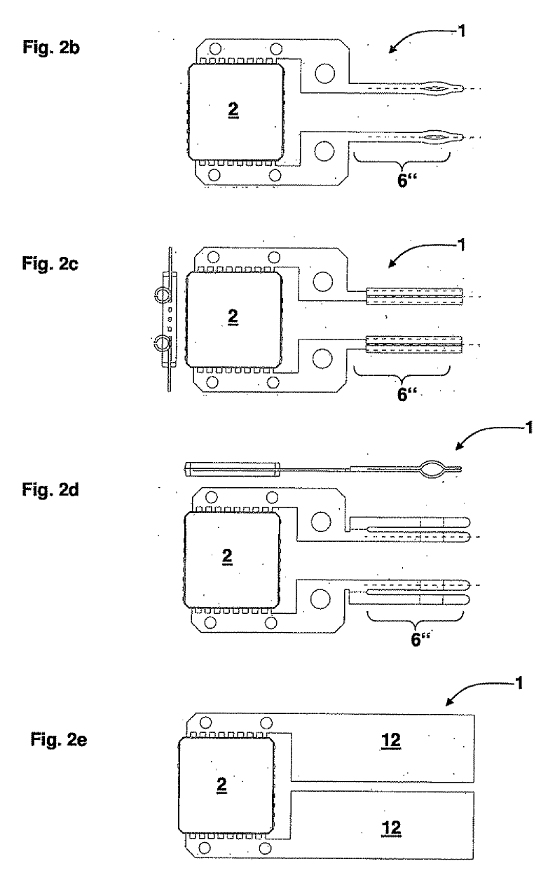

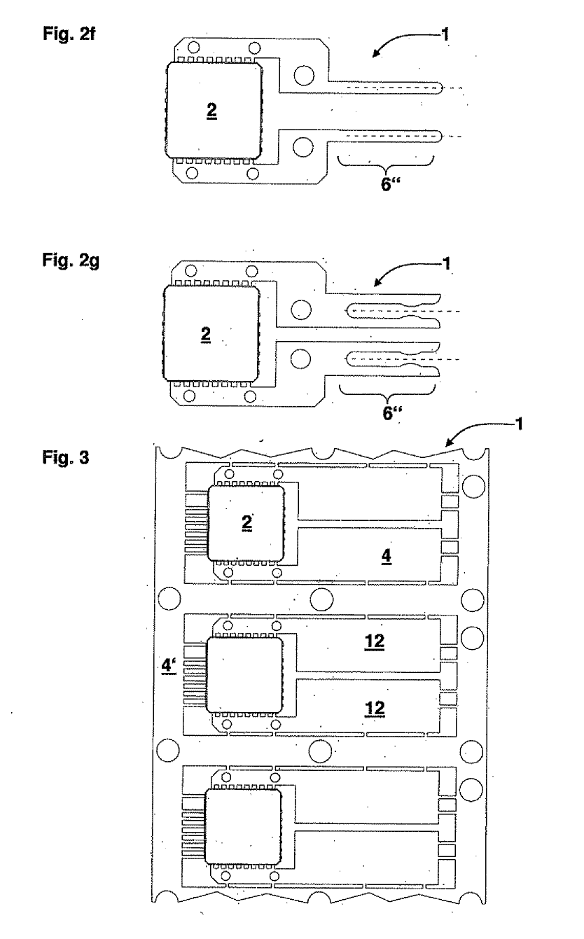

FIGS. 2a through 2g show schematic representations of additional precursor structures of module housing 1 according to additional specific embodiments of the present invention, which are generally identical to module housing 1 according to the first specific embodiment respectively without outer housing 3, only the shape of connection element 4 in third subsection 6″ varying in the additional specific embodiments so as to produce a plurality of different plug contacts 8 for different plugs 9. FIG. 2e shows a schematic representation of another precursor structure, which represents a initial basic form of connection element 4, from which all possible specific embodiments of plug contacts, for example the additional specific embodiments illustrated in FIGS. 2a through 2g, are producible by stamping-bending processes.

FIG. 3 shows a first precursor structure of a plurality of module housings 1 according to one of the additional specific embodiments, which are arranged as initial basic forms in a composite lead frame, a plurality of components 5 (not shown) being mounted in the first method step using a composite 4′ of connection elements 4, preferably being electrically contacted in a fourth method step and enclosed in a second method step by a plurality of inner housings 2. The composite 4′ of connection elements 4 and conductor tracks 12 shown on the basis of the precursor structure is stamped out in a subsequent fifth method step in such a way that individual connection elements 4 and conductor tracks 12 having respectively an inner housing 2 are produced, a process of bending and/or stamping of connection element 4 in the third subsection 6″ being preferably simultaneously provided for producing the respective plug contacts 8. In a subsequent third method step, respectively generally every inner housing 2 and every second subsection 6′ of connection element 4 is provided with an outer housing 3 by spray-coating, outer housing 3 preferably having a plug 9, and the outer shape of outer housing 3 particularly preferably being provided to be variable.

FIG. 4 shows an exemplary inner housing 2 of a module housing 1 according to one of the additional specific embodiments, inner housing 1 being a molded housing, which encloses connection element 4 in first subsection 6 in a form-locking and in particular integral manner.

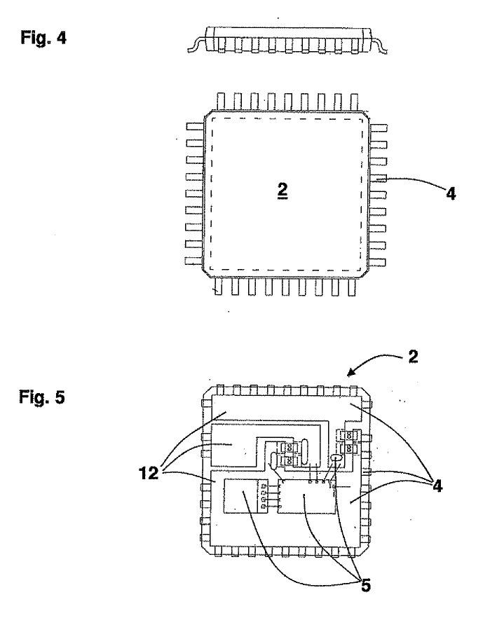

FIG. 5 likewise shows an inner housing 2 of a module housing 1 according to one of the additional specific embodiments, inner housing 2 having components 5, which include semiconductor chips and passive components. Components 5 are mounted on connection element 4 and are electrically contacted by conductor tracks 12 of connection element 4. Components 5 preferably comprise a motion sensor and an ASIC.

1-11. (canceled)

12. A module housing, comprising:
an inner housing;
an outer housing, the inner housing having at least one component and being completely enclosed by the outer housing in a form-locking manner; and
a connection element enclosed in a first subsection by the inner housing in a form-locking manner, the connection element having electrical plug contacts in a third subsection.

13. The module housing as recited in claim 12, wherein the outer housing has a plug which envelops the electrical plug contacts at least partially.

14. The module housing as recited in claim 13, wherein the electrical plug contact may have one of a number of shapes by a stamping-bending process.

15. The module housing as recited in claim 12, wherein the connection element has a connection to additional plug contacts in the third subsection, the connection being at least one of an electrical connection and a mechanical connection.

16. The module housing as recited in claim 12, wherein the at least one component has at least one of an electrical and mechanical first contact to the connection element.

17. The module housing as recited in claim 12, wherein the connection element is enclosed in a second subsection by the outer housing in a form-locking manner.

18. The module housing as recited in claim 12, wherein the connection element includes at least two electrically conductive conductor tracks, the conductor tracks extending at least partially over the first subsection of the connection element, a second subsection of the connection element and the third subsection of the connection element.

19. The module housing of the connection element as recited in claim 12, wherein at least one of the inner housing and the outer housing includes one of a molded housing or a spray-cast housing.

20. The module housing of the connection element as recited in claim 12, wherein the component includes at least one of: i) at least one semiconductor chip, and ii) at least one passive electrical component.

21. The module housing of the connection element as recited in claim 19, wherein the molded housing is one of an epoxide housing or a plastic housing.

22. A method for manufacturing a module housing, the module housing including an inner housing, an outer housing, the inner housing having at least one component and being completely enclosed by the outer housing in a form-locking manner, and a connection element enclosed in a first subsection by inner housing in a form-locking manner, the connection element having electrical plug contacts in a third subsection, the method comprising:
mounting the at least one component on the connection element;
spray-coating the at least one component and the first subsection of the connection element to produce the inner housing; and
spray-coating the inner housing and at least partially the connection element to produce the outer housing.

23. The method as recited in claim 22, further comprising:
after the mounting step, electrically contacting the at least one component by a bonding process.

24. The method as recited in claim 23, further comprising:
after the spray-coating the at least one component step, at least one of stamping and bending the connection element.

25. The method as recited in claim 24, wherein the at least one of the stamping and bonding is in a third subsection of the connection element.

26. The method as recited in claim 22, wherein, in the mounting step, a plurality of components are mounted on a composite lead frame, and in the spray-coating the at least one component step, a plurality of components is respectively spray-coated to produce a plurality of inner housings, wherein the composite is stamped so as to form a plurality of connection elements that are partially enclosed by the inner housing.

27. The method as recited in claim 22, further comprising:
performing an injection molding.

28. The method as recited in claim 22, wherein the spray-coating the at least one component includes a spray coating process.
